(19) United States
(12) Patent Application Publication
(10) Pub. No.: US 2025/0306062 A1
(43) Pub. Date: Oct. 2, 2025

(54) CURRENT SENSOR AND ELECTRONIC DEVICE

(71) Applicant: Asahi Kasei Microdevices Corporation, Tokyo (JP)

(72) Inventor: Taiga KYOSAKI, Tokyo (JP)

(21) Appl. No.: 19/088,882

(22) Filed: Mar. 24, 2025

(30) Foreign Application Priority Data
Mar. 26, 2024 (JP) 2024-049378
Mar. 12, 2025 (JP) 2025-038849

(51) Int. Cl. G01R 15/20; G01R 19/00

(52) U.S. Cl. CPC G01R 15/207; G01R 19/0092

(57) ABSTRACT

A current sensor includes a busbar and a magnetic sensor which has at least two magnetoelectric conversion elements. The busbar may have a first conductive member and a second conductive member arranged to face each other across the magnetic sensor, extending in a first direction, and a linkage member arranged between the first conductive member and the second conductive member, linking the first conductive member to the second conductive member. When viewed from sides of magnetosensitive surfaces of the at least two magnetoelectric conversion elements, the magnetic sensor may not overlap the first conductive member, the second conductive member, and the linkage member. A direction that is a direction along a magnetosensitive surface of the magnetosensitive surfaces and that intersects the first direction, is set as a second direction, when viewed from the second direction, the magnetosensitive surface may not overlap the first conductive member and the second conductive member.

The contents of the following patent application(s) are incorporated herein by reference:
NO. 2024-049378 filed in JP on Mar. 26, 2024
NO. 2025-038849 filed in JP on Mar. 12, 2025.

### BACKGROUND

### 1. Technical Field

The present invention relates to a current sensor and an electronic device.

### 2. Related Art

Patent Documents 1 and 2 disclose that a magnetic sensor is arranged on a busbar having two flow paths at the same height in a thickness direction. Patent documents 3 and 4 disclose that in a busbar having two flow paths at heights different from each other in a thickness direction, a magnetic sensor is arranged between the two flow paths to overlap the two flow paths in a planar view. Patent document 5 discloses that in a busbar having two flow paths at heights different from each other in a thickness direction, a magnetic sensor is arranged between the two flow paths to overlap the two flow paths in a planar view, or two independent busbars are arranged at heights different from each other in the thickness direction. Prior Art Documents

### Patent Document

Patent Document 1: International Publication No. WO 2023/038725
Patent Document 2: Specification of US Patent Application Publication No. 2023/0204632
Patent Document 3: Japanese Patent Application Publication No. 2021-36199
Patent Document 4: Specification of US Patent Application Publication No. 2020/0300894
Patent Document 5: International Publication No. WO 2017/010219

### BRIEF DESCRIPTION OF THE DRAWINGS

FIG. 1 is a view showing an example of a perspective view of an electronic device according to the present embodiment.

FIG. 2 is a plan view of the electronic device when viewed from a substrate side.

FIG. 3 is a side view of the electronic device when viewed from a side surface side of a busbar.

FIG. 4 is a perspective view of the busbar.

FIG. 5 is a side view of the busbar.

FIG. 6 is a plan view of the busbar.

FIG. 7 is a plan view of an electronic device according to a comparative example, when viewed from a power module side.

FIG. 8 is a diagram showing a positional relationship between the busbar and a magnetic sensor in the electronic device according to the comparative example.

FIG. 9 is a diagram showing a positional relationship between the busbar and the magnetic sensor in the electronic device according to the present embodiment.

FIG. 10 is a plan view of a metal plate which is a base of the busbar.

FIG. 11 is a plan view of the metal plate before being folded to form the busbar.

FIG. 12 is a plan view of the metal plate that is folded, that is the busbar.

FIG. 13 is a perspective view of the busbar according to a modified example.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solution of the invention.

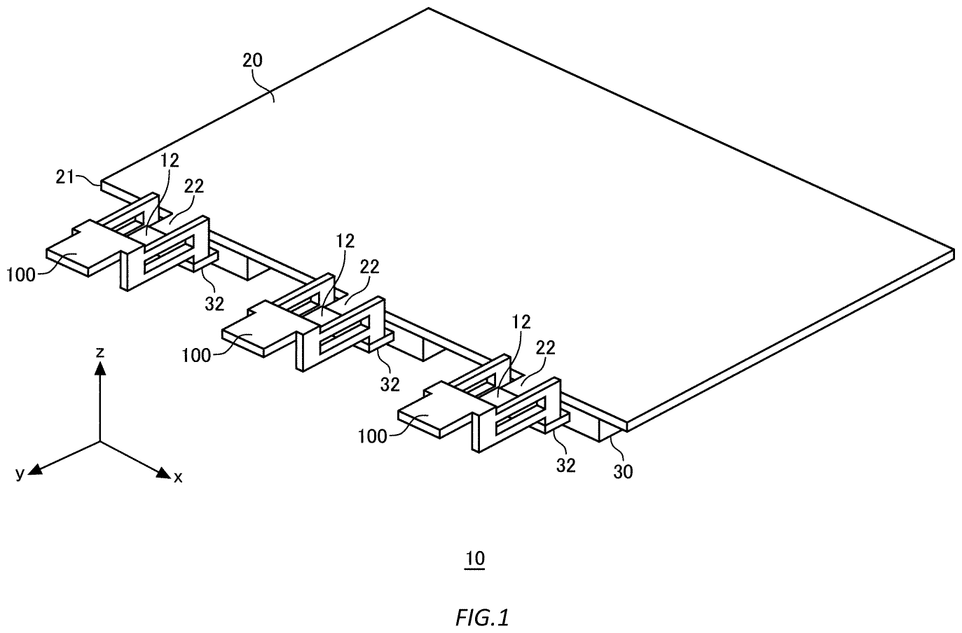

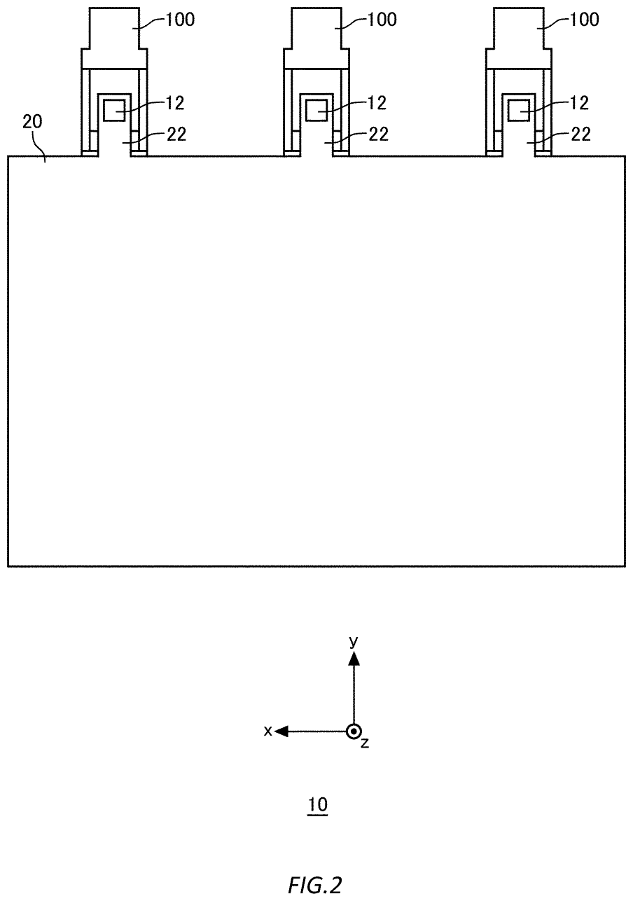

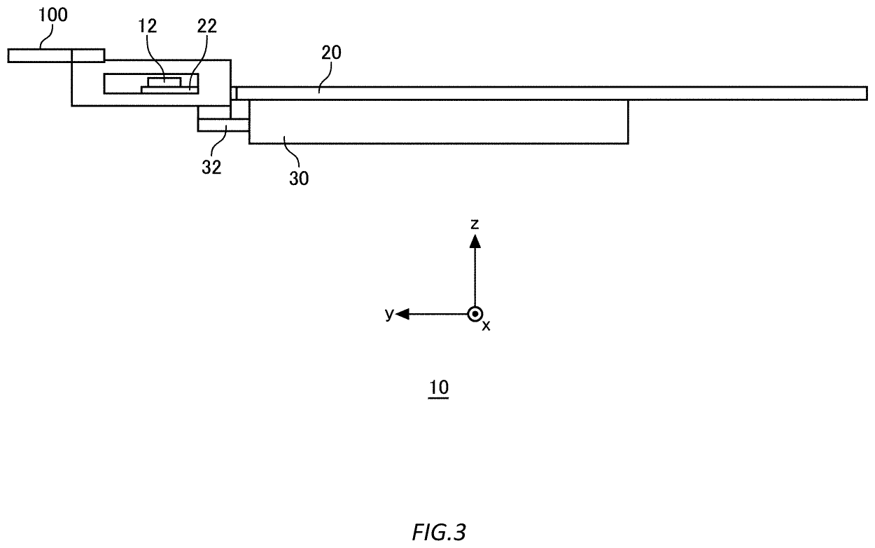

FIG. 1 shows an example of a perspective view of an electronic device 10 according to the present embodiment. The electronic device 10 includes a magnetic sensor 12, a busbar 100, a power module 30, and a substrate 20. FIG. 2 is a plan view of the electronic device 10 when viewed from a substrate 20 side. FIG. 3 is a side view of the electronic device 10 when viewed from a side surface side of the busbar 100.

The power module 30 has a plurality of output terminals 32. The plurality of output terminals 32 are arrayed to be spaced apart along one side surface of the power module 30. The power module 30 is a power converter that converts a direct current into an alternating current. The power module 30 converts the direct current to the three-phase alternating current. It should be noted that the number and positions of the output terminals 32 included in the power module 30 are not limited to those shown in FIG. 1.

The substrate 20 is arranged on a mounting surface of the power module 30. The mounting surface is an example of a first surface. The substrate 20 has a plurality of protrusion portions 22 which protrude from an edge portion 21. The plurality of protrusion portions 22 are arranged at positions facing the output terminals 32.

A plurality of magnetic sensors 12 are arranged on the plurality of protrusion portions 22, respectively. The magnetic sensor 12 has two magnetoelectric conversion elements that detect magnetic fields generated by a measurement current flowing through the busbar 100. The magnetic sensor 12 has two built-in magnetoelectric conversion elements having magnetosensitive surfaces. The magnetic sensor 12 may have three or more magnetoelectric conversion elements. A magnetoelectric conversion element may be an element of a vertical magnetic field detection type, and for example, may be a Hall element. In the present embodiment, the plurality of magnetic sensors 12 are arranged on surfaces of the plurality of protrusion portions 22 on an opposite side of a surface on which the power module 30 is mounted; however, as long as a positional relationship between the busbar 100 and the magnetic sensor 12 satisfies a relationship described below, the plurality of magnetic sensors 12 may be arranged on surfaces of the plurality of protrusion portions 22 on the same side of a surface on which the power module 30 is mounted. The plurality of magnetic sensors 12 may be arranged on any surface of each of the plurality of protrusion portions 22. That is, regardless of which surface of the protrusion portion 22 the magnetic sensor 12 is arranged on, in any case, what is meant is that the magnetic sensor 12 is arranged on the protrusion portion 22.

A plurality of busbars 100 are fixed to the plurality of output terminals 32, respectively. The busbar 100 may be welded to an output terminal 32.

The magnetic sensor 12 detects a magnetic field generated by the measurement current flowing through the busbar 100; and the magnetic sensor 12 outputs a signal in accordance with a magnitude of the magnetic field, as a signal indicating a current value of the measurement current flowing through the busbar 100. That is, a current sensor is constituted by the busbar 100 and the magnetic sensor 12. The present embodiment describes an example in which the substrate 20 is arranged on the mounting surface of the power module 30; however, as long as a positional relationship between the busbar 100 and the magnetic sensor 12 satisfies a relationship described below, the busbar 100 may be provided on a surface of the substrate 20 on which plurality of magnetic sensors 12 are provided.

The plurality of protrusion portions 22 on the substrate 20 are preferably arranged without being in contact with the busbars 100. This makes it easy to ensure insulation between the busbar 100 and the magnetic sensor 12. On the substrate 20 on which the busbars 100 and the plurality of magnetic sensors 12 are mounted, in a case where the plurality of protrusion portions 22 are arranged without being in contact with the busbars 100, the substrate 20 and the busbar 100 may be positioned by being fixed to the power module 30.

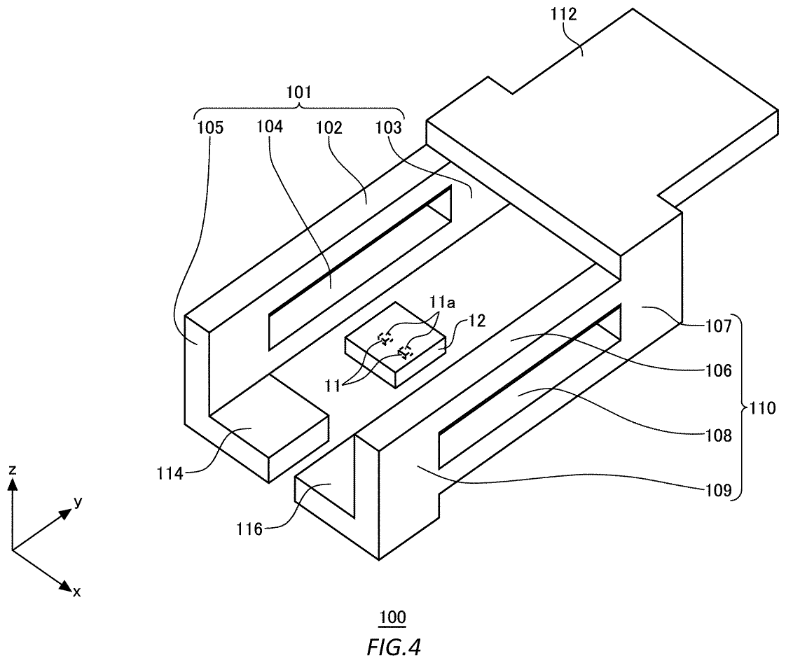

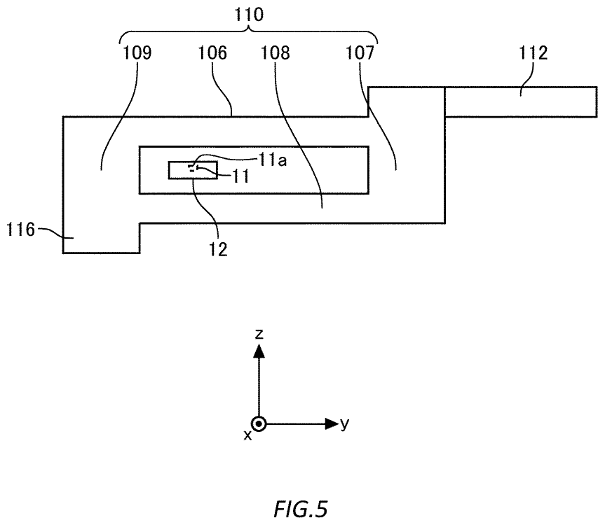

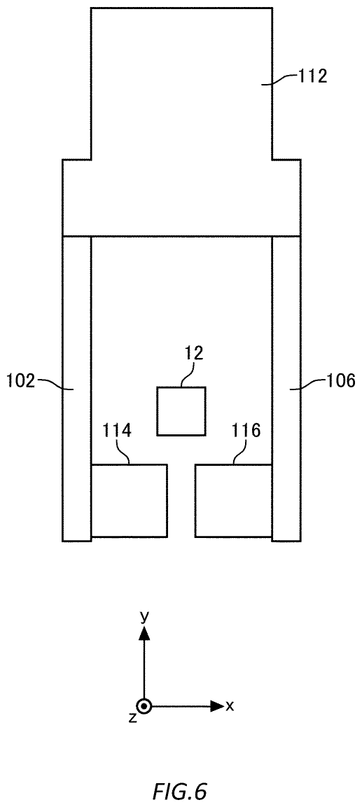

FIG. 4 is a perspective view of the busbar 100. FIG. 5 is a side view of the busbar 100. FIG. 6 is a plan view of the busbar 100. FIG. 4 to FIG. 6 also show the positional relationship between the busbar 100 and the magnetic sensor 12.

The busbar 100 extends in a first direction (a y axis); and has a first conductive member 101 and a second conductive member 110 which are arranged to be spaced apart from each other. The busbar 100 further has a linkage member 112 which is arranged between the first conductive member 101 and the second conductive member 110, and links the first conductive member 101 to the second conductive member 110. The busbar 100 may be constituted by a conductive material of which a main component is copper.

The first conductive member 101 has a first flow path portion 102 and a second flow path portion 104 through which the measurement current flows. The first flow path portion 102 and the second flow path portion 104 are spaced apart from each other, and extend in the first direction. The first conductive member 101 further has a first linkage portion 103 and a second linkage portion 105 which are arranged to be spaced apart from each other, and link the first flow path portion 102 to the second flow path portion 104. The first linkage portion 103 and the second linkage portion 105 may link both ends of the first flow path portion 102 and the second flow path portion 104, respectively.

The second conductive member 110 has a third flow path portion 106 and a fourth flow path portion 108 through which the measurement current flows. The third flow path portion 106 and the fourth flow path portion 108 are spaced apart from each other, and extend in the first direction. The second conductive member 110 further has a third linkage portion 107 and a fourth linkage portion 109 which are arranged to be spaced apart from each other, and link the third flow path portion 106 to the fourth flow path portion 108. The third linkage portion 107 and the fourth linkage portion 109 may link both ends of the third flow path portion 106 and the fourth flow path portion 108, respectively. The first linkage portion 103 and the third linkage portion 107 may be arranged to face each other in a second direction (an x axis direction) intersecting the first direction (a y axis direction); and the second linkage portion 105 and the fourth linkage portion 109 may be arranged to face each other in the second direction (the x axis direction).

The busbar 100 has a first terminal connection member 114 which is linked to the first conductive member 101, and protrudes from the second linkage portion 105 to a fourth linkage portion 109 side. The busbar 100 has a second terminal connection member 116 which is linked to the second conductive member 110, and protrudes from the fourth linkage portion 109 to a second linkage portion 105 side. The first terminal connection member 114 and the second terminal connection member 116 may be fixed to the output terminal 32 by welding or the like.

When viewed from a magnetosensitive surface 11a side (a positive side in a z axis direction) of a magnetoelectric conversion element 11, the magnetic sensor 12 does not overlap the first conductive member 101, the second conductive member 110, and the linkage member 112. When viewed from the magnetosensitive surface 11a side (the positive side in the z axis direction) of the magnetoelectric conversion element 11, the magnetic sensor 12 may not overlap the first terminal connection member 114 and the second terminal connection member 116. Furthermore, when viewed from the second direction (the x axis direction) that is along a magnetosensitive surface 11a and that intersects the first direction (the y axis direction), the magnetosensitive surface 11a of the magnetoelectric conversion element 11 does not overlap the first conductive member 101 and the second conductive member 110, and is arranged between at least a part of the first conductive member 101 and at least a part of the second conductive member 110. When viewed from the second direction, the magnetosensitive surface 11a may be arranged: between the first flow path portion 102 and the second flow path portion 104, between the first linkage portion 103 and the second linkage portion 105; and between the third flow path portion 106 and the fourth flow path portion 108, between the third linkage portion 107 and the fourth linkage portion 109.

When viewed from the second direction, the magnetic sensor 12 may not overlap the first conductive member 101 and the second conductive member 110. The magnetic sensor 12 may be arranged: between the first flow path portion 102 and the second flow path portion 104, between the first linkage portion 103 and the second linkage portion 105; and between the third flow path portion 106 and the fourth flow path portion 108, between the third linkage portion 107 and the fourth linkage portion 109.

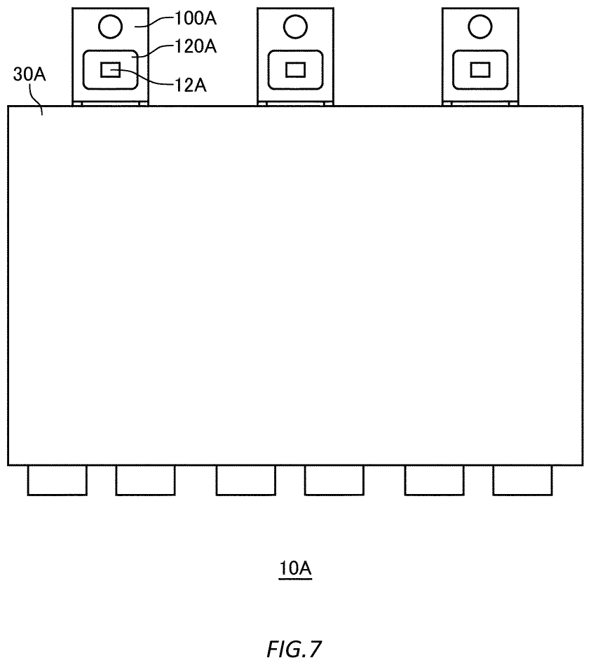

FIG. 7 is a plan view of an electronic device 10A according to a comparative example, when viewed from a power module 30 side. A magnetic sensor 12A is arranged in an opening 120A which is included in a busbar 100A.

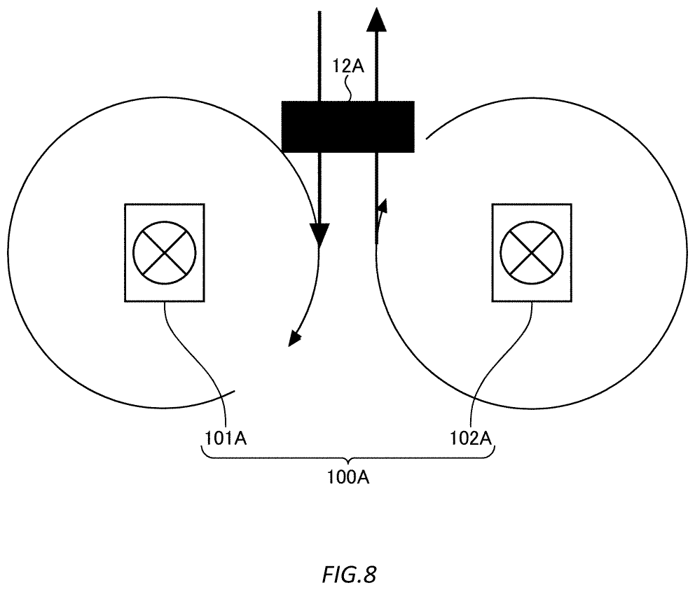

In a case of such a configuration, the magnetic sensor 12A is positioned between a flow path 101A and a flow path 102A of two currents, as shown in FIG. 8. That is, when viewed from the second direction, the magnetic sensor 12A overlaps the first conductive member 101 and the second conductive member 110. The magnetic sensor 12A existing at such a position detects a magnetic field in a direction as shown in FIG. 8, according to a so-called right-hand screw rule. When a position of the magnetic sensor 12A existing in such a position is deviated in a direction perpendicular to the magnetosensitive surface, in the magnitude of the magnetic field that is detected by the magnetoelectric conversion element included in the magnetic sensor 12A, a deviation is likely to occur. That is, in the measurement value in accordance with the magnitude of the magnetic field that is measured by the magnetic sensor 12A, there is a high possibility that an error occurs due to a positional deviation in the direction perpendicular to the magnetosensitive surface of the magnetic sensor 12A.

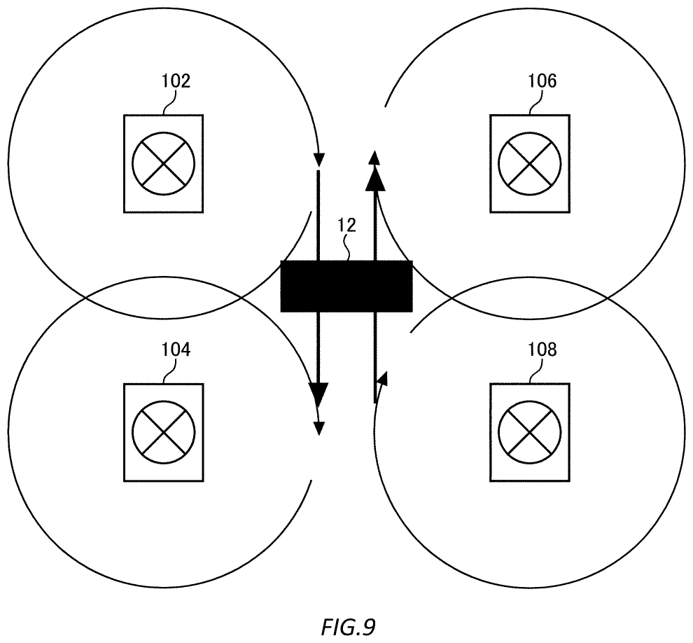

On the other hand, according to the configuration of the electronic device 10 according to the present embodiment, as shown in FIG. 9, the magnetic sensor 12 exists between the flow paths of the currents at heights different from each other in the direction perpendicular to the magnetosensitive surface. More specifically, the magnetic sensor 12 exists to be surrounded by the total four flow paths of the first flow path portion 102, the second flow path portion 104, the third flow path portion 106, and the fourth flow path portion 108. In this way, due to the existence of the flow paths of the currents at heights different from each other in the direction perpendicular to the magnetosensitive surface, even when the position of the magnetic sensor 12 is deviated in the direction perpendicular to the magnetosensitive surface, in the magnitude of the magnetic field that is detected by the magnetoelectric conversion element included in the magnetic sensor 12, a deviation is less likely to occur. Therefore, in the measurement value in accordance with the magnitude of the magnetic field that is measured by the magnetic sensor 12, an error due to a positional deviation in the direction perpendicular to the magnetosensitive surface of the magnetic sensor 12, is less likely to occur.

For example, when the magnetic sensor 12A according to the comparative example is deviated by 0.1 mm in the direction perpendicular to the magnetosensitive surface, in the measurement value that is measured by the magnetic sensor 12A, that is, the current value, an error of 2% or more occurs as a result of a simulation. On the other hand, when the magnetic sensor 12 according to the present embodiment is deviated by 0.1 mm in the direction perpendicular to the magnetosensitive surface, the current value that is measured by the magnetic sensor 12, is obtained by an error of 0.5% or less as a result of a simulation.

In addition, the magnetic sensor 12 is provided on the protrusion portion 22 provided on the edge portion 21 of the substrate 20. When viewed from the magnetosensitive surface 11a side of the magnetoelectric conversion element 11, the protrusion portion 22 and the magnetic sensor 12 do not overlap the first conductive member 101, the second conductive member 110, and the linkage member 112. When viewed from the magnetosensitive surface 11a side of the magnetoelectric conversion element 11, the protrusion portion 22 and the magnetic sensor 12 are positioned between the first conductive member 101 and the second conductive member 110.

By setting such a configuration, in a state in which the busbar 100 is fixed to the output terminal 32 of the power module 30, by moving the substrate 20, which has the magnetic sensor 12 mounted on the protrusion portion 22, from above the mounting surface of the power module 30 along the direction (the z axis direction) perpendicular to the mounting surface, it is possible to arrange the substrate 20 on the mounting surface of the power module 30. The power module 30 and the substrate 20 may be positioned by, for example, press-fit pins.

The busbar 100 may be fixed to the output terminal 32 of the power module 30 by welding, and the magnetic sensor 12 may be fixed to the substrate 20 by soldering. Therefore, by positioning the power module 30 and the substrate 20 with a high precision so as to make a predetermined positional relationship by the press-fit pins or the like, the magnetic sensor 12 and the busbar 100 are also positioned with a high precision.

Subsequently, a method of manufacturing the busbar 100 will be described.

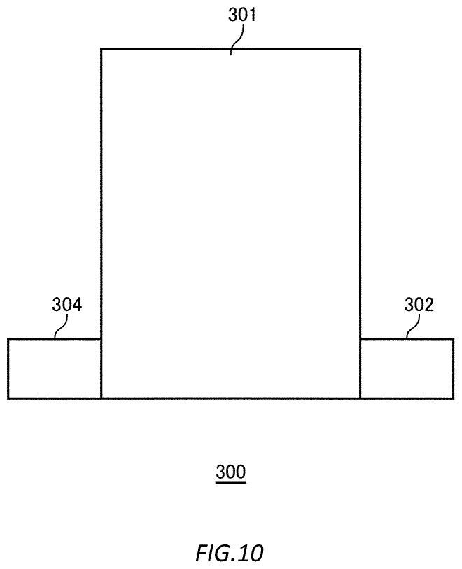

FIG. 10 shows a metal plate 300 which is a base of the busbar 100. The metal plate 300 has a main body portion 301, and an extension portion 302 and an extension portion 304. The extension portion 302 and the extension portion 304 extend along a short direction on both sides of one end of the main body portion 301 in a longitudinal direction. The metal plate 300 has a T shape in a planar view.

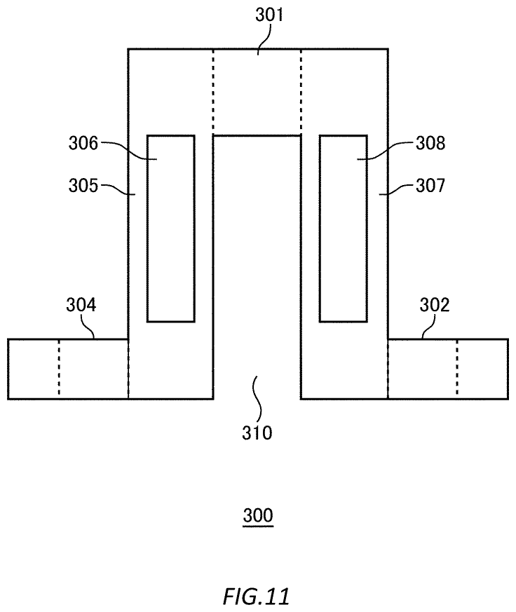

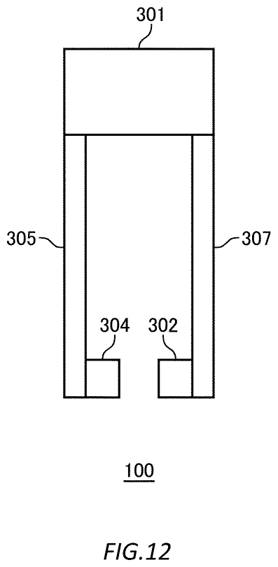

The metal plate 300 undergoes a cutting out process as shown in FIG. 11. That is, on the main body portion 301, cutting out is performed from the center of one end of the main body portion 301 in the longitudinal direction toward another end of the main body portion 301 in the longitudinal direction, a groove 310 is formed, and the main body portion 301 makes a U shape. An opening 306 and an opening 308 are formed along the longitudinal direction, in a first portion 305 and a second portion 307 which face each other across the groove 310 of the main body portion 301. Then, the metal plate 300 is folded inward along dashed lines, as folding lines, shown in FIG. 11, thereby forming the busbar 100 as shown in FIG. 12.

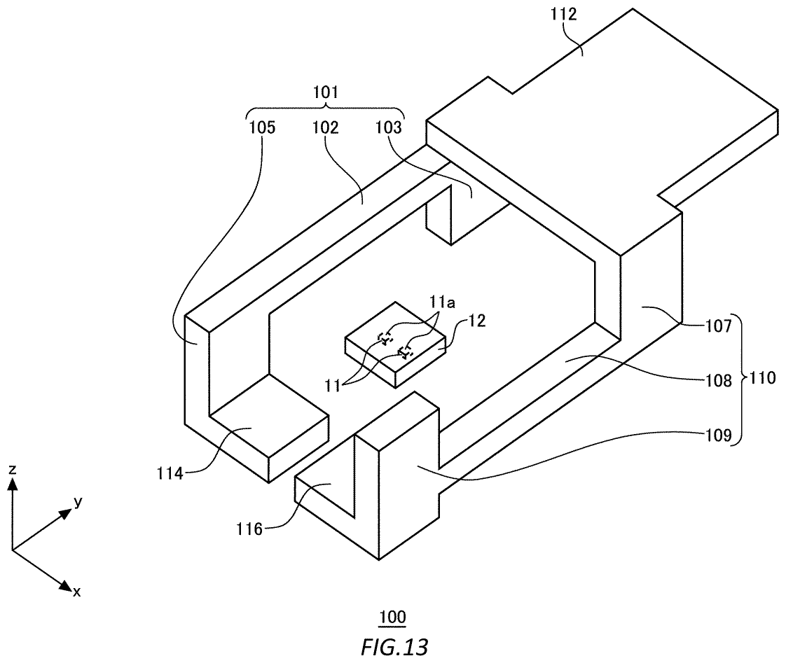

In the above embodiment, the busbar 100 is described as an example in which the magnetic sensor is surrounded by four flow paths. However, the busbar 100 may have only two flow paths which are diagonally positioned, among the first flow path portion 102, the second flow path portion 104, the third flow path portion 106, and the fourth flow path portion 108. That is, the busbar 100 may have the first flow path portion 102 and the fourth flow path portion 108, and may not have the second flow path portion 104 and the third flow path portion 106, as shown in FIG. 13. Alternatively, the busbar 100 may have the second flow path portion 104 and the third flow path portion 106, and may not have the first flow path portion 102 and the fourth flow path portion 108.

As described above, with the electronic device 10 of the present embodiment, it is possible to enhance ease of mounting the magnetic sensor 12 on the power module 30 while suppressing a detection error due to a positional deviation of the magnetic sensor 12 in the thickness direction.

While the present invention has been described above with the embodiments, the technical scope of the present invention is not limited to the above-described embodiments. It is apparent to persons skilled in the art that various alterations or improvements can be made to the above-described embodiments. It is also apparent from description of the claims that the embodiments to which such changes or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

(Item 1)

A current sensor including: a busbar through which a measurement current flows; and a magnetic sensor having at least two magnetoelectric conversion elements which detect a magnetic field that is generated by a measurement current flowing through the busbar in which
the busbar has
a first conductive member and a second conductive member which are arranged to face each other across the magnetic sensor, and extend in a first direction, and
a linkage member which is arranged between the first conductive member and the second conductive member, and links the first conductive member to the second conductive member,
when viewed from sides of magnetosensitive surfaces of the at least two magnetoelectric conversion elements, the magnetic sensor does not overlap the first conductive member, the second conductive member, and the linkage member,
a direction that is a direction along a magnetosensitive surface of the magnetosensitive surfaces and that intersects the first direction, is set as a second direction, and
when viewed from the second direction, the magnetosensitive surface does not overlap the first conductive member and the second conductive member, and is arranged between at least a part of the first conductive member and at least a part of the second conductive member.

(Item 2)

The current sensor according to item 1, in which the first conductive member has a first flow path portion and a second flow path portion which are spaced apart from each other, and extend in the first direction, and through which the measurement current flows, and a first linkage portion and a second linkage portion which are arranged to be spaced apart from each other, and respectively link the first flow path portion to the second flow path portion,
the second conductive member has a third flow path portion and a fourth flow path portion which are spaced apart from each other, and extend in the first direction, and through which the measurement current flows, and a third linkage portion and a fourth linkage portion which are arranged to be spaced apart from each other, and link the third flow path portion to the fourth flow path portion, and
when viewed from the second direction, the magnetosensitive surface is arranged: between the first flow path portion and the second flow path portion, between the first linkage portion and the second linkage portion; and between the third flow path portion and the fourth flow path portion, between the third linkage portion and the fourth linkage portion.

(Item 3)

The current sensor according to item 1, in which when viewed from the second direction, the magnetic sensor does not overlap the first conductive member and the second conductive member.

(Item 4)

The current sensor according to item 1, in which when viewed from the second direction, the magnetosensitive surface is arranged between the first conductive member and the second conductive member.

(Item 5)

The current sensor according to item 1, in which the at least two magnetoelectric conversion elements are elements of a vertical magnetic field detection type.

(Item 6)

An electronic device including: the current sensor according to any one of items 1 to 5; an electronic module which has an output terminal; and

a substrate which is arranged at a predetermined position on a first surface of the electronic module, in which
the busbar is fixed to the output terminal, and
the magnetic sensor is arranged on the substrate.

(Item 7)

The electronic device according to item 6, in which the substrate has a protrusion portion which protrudes from an edge portion, and
the magnetic sensor is arranged on the protrusion portion.

(Item 8)

The electronic device according to item 7, in which when viewed from sides of magnetosensitive surfaces of the at least two magnetoelectric conversion elements, the protrusion portion does not overlap the first conductive member and the second conductive member.

(Item 9)

The electronic device according to item 7, in which the protrusion portion is arranged between the first conductive member and the second conductive member.

(Item 10)

The electronic device according to item 6, in which the first conductive member has a first flow path portion and a second flow path portion which are spaced apart from each other, and extend in the first direction, and through which the measurement current flows, and a first linkage portion and a second linkage portion which are arranged to be spaced apart from each other, and link the first flow path portion to the second flow path portion,
the second conductive member has a third flow path portion and a fourth flow path portion which are spaced apart from each other, and extend in the first direction, and through which the measurement current flows, and a third linkage portion and a fourth linkage portion which are arranged to be spaced apart from each other, and link the third flow path portion to the fourth flow path portion,
the linkage member links the first linkage portion to the third linkage portion,
the busbar further has
a first terminal connection member which is linked to the first conductive member, and protrudes from the second linkage portion to a fourth linkage portion side, and
a second terminal connection member which is linked to the second conductive member, and protrudes from the fourth linkage portion to a second linkage portion side, the first terminal connection member and the second terminal connection member are fixed to the output terminal, and
when viewed from a second direction that is along the magnetosensitive surface and that intersects the first direction, the magnetosensitive surface is arranged: between the first flow path portion and the second flow path portion, between the first linkage portion and the second linkage portion; and between the third flow path portion and the fourth flow path portion, between the third linkage portion and the fourth linkage portion.

(Item 11)

The electronic device according to item 7, in which the electronic module includes a plurality of output terminals, each of which is identical to the output terminal,
the substrate has a plurality of protrusion portions, each of which is identical to the protrusion portion, and which protrude from the edge portion, and are arranged to be spaced apart from each other,
the current sensor includes a plurality of busbars, each of which is identical to the busbar, and a plurality of magnetic sensors, each of which is identical to the magnetic sensor, and
the plurality of magnetic sensors are respectively arranged on the plurality of protrusion portions.

(Item 12)

The electronic device according to item 11, in which the electronic module is a power module.

(Item 13)

An electronic device including: a current sensor;
an electronic module which has an output terminal; and
a substrate which is arranged at a predetermined position on a first surface of the electronic module, in which
the current sensor includes:
a busbar through which a measurement current flows; and
a magnetic sensor having at least two magnetoelectric conversion elements which detect a magnetic field that is generated by a measurement current flowing through the busbar; in which
the busbar has
a first conductive member and a second conductive member which are arranged to face each other across the magnetic sensor, and extend in a first direction, and
a linkage member which is arranged between the first conductive member and the second conductive member, and links the first conductive member to the second conductive member,
when viewed from sides of magnetosensitive surfaces of the at least two magnetoelectric conversion elements, the magnetic sensor does not overlap the first conductive member, the second conductive member, and the linkage member,
a direction that is a direction along a magnetosensitive surface of the magnetosensitive surfaces and that intersects the first direction, is set as a second direction,
when viewed from the second direction, the magnetosensitive surface does not overlap the first conductive member and the second conductive member, and is arranged between at least a part of the first conductive member and at least a part of the second conductive member,
the busbar is fixed to the output terminal,
the magnetic sensor is arranged on the substrate,
the substrate has a protrusion portion which protrudes from an edge portion, and
the magnetic sensor is arranged on the protrusion portion.

### EXPLANATION OF REFERENCES

10A: electronic device; 10A: electronic device; 11: magnetoelectric conversion element; 11a: magnetosensitive surface; 12, 12A: magnetic sensor; 20: substrate; 21: edge portion; 22: protrusion portion; 30: power module; 32: output terminal; 100, 100A: busbar; 101A, 102A: flow path; 101: first conductive member; 110: second conductive member; 102: first flow path portion; 103: first linkage portion; 104: second flow path portion; 105: second linkage portion; 106: third flow path portion; 107: third linkage portion; 108: fourth flow path portion; 109: fourth linkage portion; 112: linkage member; 114: first terminal connection member; 116: second terminal connection member; 300: metal plate; 301: main body portion; 302, 304: extension portion.

What is claimed is:

1. A current sensor comprising:
a busbar through which a measurement current flows; and
a magnetic sensor having at least two magnetoelectric conversion elements which detect a magnetic field that is generated by a measurement current flowing through the busbar, wherein
the busbar has
a first conductive member and a second conductive member which are arranged to face each other across the magnetic sensor, and extend in a first direction, and
a linkage member which is arranged between the first conductive member and the second conductive member, and links the first conductive member to the second conductive member,
when viewed from sides of magnetosensitive surfaces of the at least two magnetoelectric conversion elements, the magnetic sensor does not overlap the first conductive member, the second conductive member, and the linkage member,
a direction that is a direction along a magnetosensitive surface of the magnetosensitive surfaces and that intersects the first direction, is set as a second direction, and
when viewed from the second direction, the magnetosensitive surface does not overlap the first conductive member and the second conductive member, and is arranged between at least a part of the first conductive member and at least a part of the second conductive member.

2. The current sensor according to claim 1, wherein
the first conductive member has
a first flow path portion and a second flow path portion which are spaced apart from each other, and extend in the first direction, and through which the measurement current flows, and
a first linkage portion and a second linkage portion which are arranged to be spaced apart from each other, and respectively link the first flow path portion to the second flow path portion,
the second conductive member has
a third flow path portion and a fourth flow path portion which are spaced apart from each other, and extend in the first direction, and through which the measurement current flows, and
a third linkage portion and a fourth linkage portion which are arranged to be spaced apart from each other, and link the third flow path portion to the fourth flow path portion, and
when viewed from the second direction, the magnetosensitive surface is arranged: between the first flow path portion and the second flow path portion, between the first linkage portion and the second linkage portion; and between the third flow path portion and the fourth flow path portion, between the third linkage portion and the fourth linkage portion.

3. The current sensor according to claim 1, wherein when viewed from the second direction, the magnetic sensor does not overlap the first conductive member and the second conductive member.

4. The current sensor according to claim 1, wherein when viewed from the second direction, the magnetosensitive surface is arranged between the first conductive member and the second conductive member.

5. The current sensor according to claim 1, wherein the at least two magnetoelectric conversion elements are elements of a vertical magnetic field detection type.

6. An electronic device comprising:
the current sensor according to claim 1;
an electronic module which has an output terminal; and
a substrate which is arranged at a predetermined position on a first surface of the electronic module, wherein
the busbar is fixed to the output terminal, and
the magnetic sensor is arranged on the substrate.

7. The electronic device according to claim 6, wherein
the substrate has a protrusion portion which protrudes from an edge portion, and
the magnetic sensor is arranged on the protrusion portion.

8. The electronic device according to claim 7, wherein when viewed from sides of magnetosensitive surfaces of the at least two magnetoelectric conversion elements, the protrusion portion does not overlap the first conductive member and the second conductive member.

9. The electronic device according to claim 7, wherein the protrusion portion is arranged between the first conductive member and the second conductive member.

10. The electronic device according to claim 6, wherein
the first conductive member has a
first flow path portion and a second flow path portion which are spaced apart from each other, and extend in the first direction, and through which the measurement current flows, and
a first linkage portion and a second linkage portion which are arranged to be spaced apart from each other, and link the first flow path portion to the second flow path portion,
the second conductive member has
a third flow path portion and a fourth flow path portion which are spaced apart from each other, and extend in the first direction, and through which the measurement current flows, and
a third linkage portion and a fourth linkage portion which are arranged to be spaced apart from each other, and link the third flow path portion to the fourth flow path portion,
the linkage member links the first linkage portion to the third linkage portion,
the busbar further has
a first terminal connection member which is linked to the first conductive member, and protrudes from the second linkage portion to a fourth linkage portion side, and
a second terminal connection member which is linked to the second conductive member, and protrudes from the fourth linkage portion to a second linkage portion side,
the first terminal connection member and the second terminal connection member are fixed to the output terminal, and
when viewed from a second direction that is along the magnetosensitive surface and that intersects the first direction, the magnetosensitive surface is arranged: between the first flow path portion and the second flow path portion, between the first linkage portion and the second linkage portion; and between the third flow path portion and the fourth flow path portion, between the third linkage portion and the fourth linkage portion.

11. The electronic device according to claim 7, wherein
the electronic module includes a plurality of output terminals, each of which is identical to the output terminal,
the substrate has a plurality of protrusion portions, each of which is identical to the protrusion portion, and which protrude from the edge portion, and are arranged to be spaced apart from each other,
the current sensor includes a plurality of busbars, each of which is identical to the busbar, and a plurality of magnetic sensors, each of which is identical to the magnetic sensor, and
the plurality of magnetic sensors are respectively arranged on the plurality of protrusion portions.

12. The electronic device according to claim 11, wherein the electronic module is a power module.
